(19) United States
(12) Patent Application Publication
(10) Pub. No.: US 2009/0322311 A1
(43) Pub. Date: Dec. 31, 2009

(54) Method and Apparatus for On-Chip Testing of High Speed Frequency Dividers

(75) Inventors: Jieming Qi, Austin, TX (US); Eskinder Hailu, Sunnyvale, CA (US); David William Boerstler, Round Rock, TX (US); Masaaki Kaneko, Round Rock, TX (US)

Correspondence Address: HAMILTON & TERRILE, LLP;IBM Austin, P.O. BOX 203518, AUSTIN, TX, 78720, US

(73) Assignee: International Business Machines Corporation

(21) Appl. No.: 12/163,166

(22) Filed: Jun. 27, 2008

(51) Int. Cl. G01R 23/02; G06F 1/04

(52) U.S. Cl. 324/76.39; 327/295

(57) ABSTRACT

Embodiments of the disclosure provide systems and methods for using a PLL and a high frequency generator outside the loop to obtain the fmax of the divider. The divider in the PLL loop is fed by a VCO and its operation range is characterized by measuring the PLL lock range. An identical copy of the same divider is used outside the PLL loop and it is fed by a higher frequency clock. The high frequency clock is generated by the multiple phase of the VCO. By characterizing the outputs from both dividers, the fmax of the divider is obtained.

### BACKGROUND OF THE INVENTION

1. Field of the Invention

The present invention relates in general to the field of integrated circuits. More specifically, the present invention relates to improvements in the testing of frequency divider circuits implemented in various embodiments of integrated circuits.

2. Description of the Related Art

With semiconductor process technology scaling down to 45 nm or beyond, the maximum frequency (fmax) achievable for an on-chip phase-locked loop (PLL) is more than 30 Ghz using CMOS process. The fmax limitation is mainly due to the fmax of the voltage-controlled oscillator (VCO) and frequency divider circuitry used in the PLL. In prior testing techniques for testing the fmax of a divider, a high-frequency on-chip signal source such as a VCO is used since an external high-speed clock generator is not available. As a result, the fmax obtained from such testing is a combination of the operating characteristics of the VCO and the divider. To increase the fmax of modern PLL, it is necessary to is necessary to obtain more accurate measurements of the fmax of the divider to determine whether the VCO or the divider is the bottleneck. An improved technique for measuring the fmax of a divider is provided by embodiments of the present invention, as described in greater detail hereinbelow.

### SUMMARY OF THE INVENTION

Embodiments of the invention provide a system and method for measuring the fmax of very high speed frequency divider.

Embodiments of the invention use a PLL and a high frequency generator outside the loop to obtain the fmax of the divider. The divider in the PLL loop is fed by a VCO and its operation range is characterized by measuring the PLL lock range. An identical copy of the same divider is used outside the PLL loop and it is fed by a higher frequency clock. The high frequency clock is generated by the multiple phase of the VCO. By characterizing the outputs from both dividers, the fmax of the divider is obtained.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 a phase-locked loop circuitry for testing the maximum operating frequency of a frequency divider.

FIG. 2 shows a plurality of clock signals generated by plural stages of a voltage-controlled oscillator in the phase-locked loop of FIG. 1.

FIG. 3 shows exclusive “OR” logic implemented in the frequency multiplier of the circuit shown in FIG. 1 to generate an input signal for a frequency divider being tested.

FIG. 4 is a graphical illustration of ratios of test frequencies used in embodiments of the invention.

### DETAILED DESCRIPTION

Various illustrative embodiments of the present invention will now be described in detail with reference to the accompanying figures. It will be understood that the flowchart illustrations and/or block diagrams described herein can be implemented in whole or in part by dedicated hardware circuits, firmware and/or computer program instructions which are provided to a processor of a general purpose computer, special purpose computer, or other programmable data processing apparatus to produce a machine, such that the instructions (which execute via the processor of the computer or other programmable data processing apparatus) implement the functions/acts specified in the flowchart and/or block diagram block or blocks. In addition, while various details are set forth in the following description, it will be appreciated that the present invention may be practiced without these specific details, and that numerous implementation-specific decisions may be made to the invention described herein to achieve the device designer's specific goals, such as compliance with technology or design-related constraints, which will vary from one implementation to another. While such a development effort might be complex and time-consuming, it would nevertheless be a routine undertaking for those of ordinary skill in the art having the benefit of this disclosure. For example, selected aspects are shown in block diagram form, rather than in detail, in order to avoid limiting or obscuring the present invention. In addition, some portions of the detailed descriptions provided herein are presented in terms of algorithms or operations on data within a computer memory. Such descriptions and representations are used by those skilled in the art to describe and convey the substance of their work to others skilled in the art. Various illustrative embodiments of the present invention will now be described in detail below with reference to the figures.

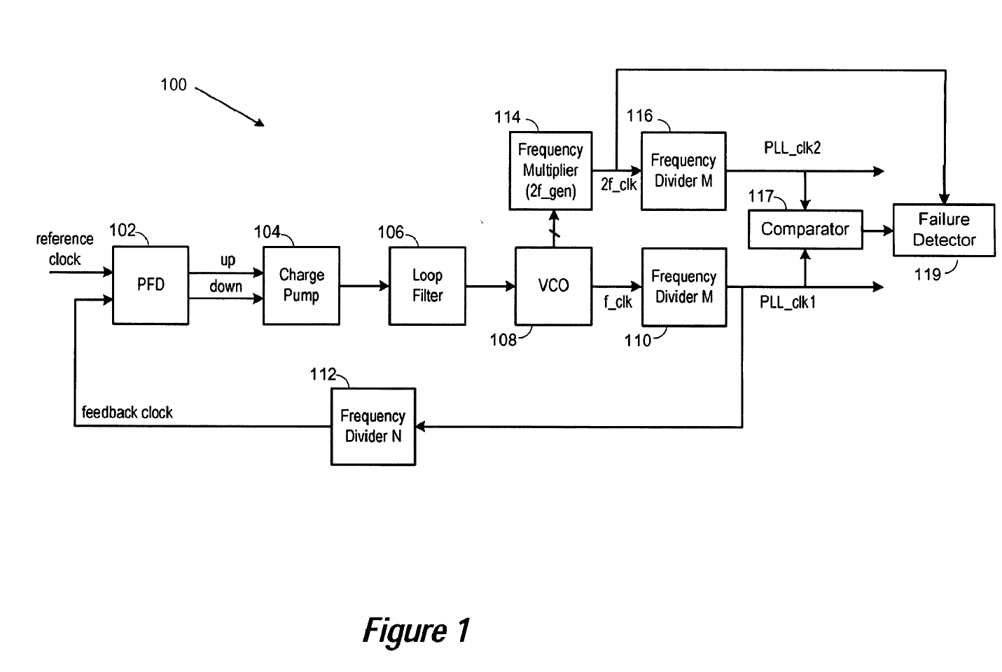

FIG. 1 is an illustration of an embodiment of a system 100 for measuring the fmax of a frequency divider. The system includes a phase-locked loop comprising a phase-frequency detector (PFD) 102, charge pump 104, loop filter 106, and a VCO 108. Operation of these components is well understood by those of skill in the art and, therefore, the operation of these components is not described in detail herein. The frequency divider 110 receives the output signal, f_clk, of the VCO 108 and divides it by a predetermined factor “M” to generate a desired PLL clock signal, PLL_clk1 at a predetermined frequency. The PLL clock signal is also provided as an input to frequency divider 112 that is operable to divide it by a predetermined factor “N” to generate the loop feedback clock. The frequency multiplier 114 is operable to receive the output signal of the VCO 108 and to generate a clock having frequency that is a predetermined multiple of the VCO output signal. The frequency divider 116 receives the clock signal generated by the frequency multiplier 114 and divides it by a predetermined factor “M” to generate a second PLL clock signal, PLL_clk2, having a higher frequency than PLL_clk1. The frequency divider 116 is fabricated to have operating characteristics that are identical to the operating characteristics of frequency divider 110. Furthermore, the frequency dividers 110 and 116 each divide by the same predetermined factor “M.” Therefore, the PLL_clk2 signal will have a fixed relationship with respect to PLL_clk1, the ratio of these two clock signals will be equal to the ratio of clock signals provided as inputs to the frequency dividers 110 and 116 as long as frequency divider 116 is operating at or below it's fmax. Comparator 117 measures the ratio of the PLL_clk1 and PLL_clk2 signals and generates an output signal that is used by failure detector 119 to log the frequency of PLL_clk1 (fmax) at the time the ratio between the two PLL clocks no longer have the correct ratio. The failure detector 119 receives the output clock signal of the frequency multiplier. Thus the fmax of the frequency divider 110 will be the highest frequency of the output signal from the frequency multiplier 114 prior to failure of the frequency divider 116.

In some embodiments of the invention, the frequency multiplier 114 generates a clock signal, 2f_clk, that is twice the frequency of the clock signal that is provided as an input to the frequency divider 110. In principle, the multiplication factor used by the frequency multiplier 114 can be an quantity that generates a clock signal that is larger than the frequency of the output signal generated by the VCO 108. For example, it can 1.5 times or 2 times of the VCO frequency. For simplicity, the discussion herein will illustrate an example embodiment of the invention where the signal, “2f_clock,” generated by the frequency multiplier 114 is twice the frequency of the output signal generated by the VCO 108.

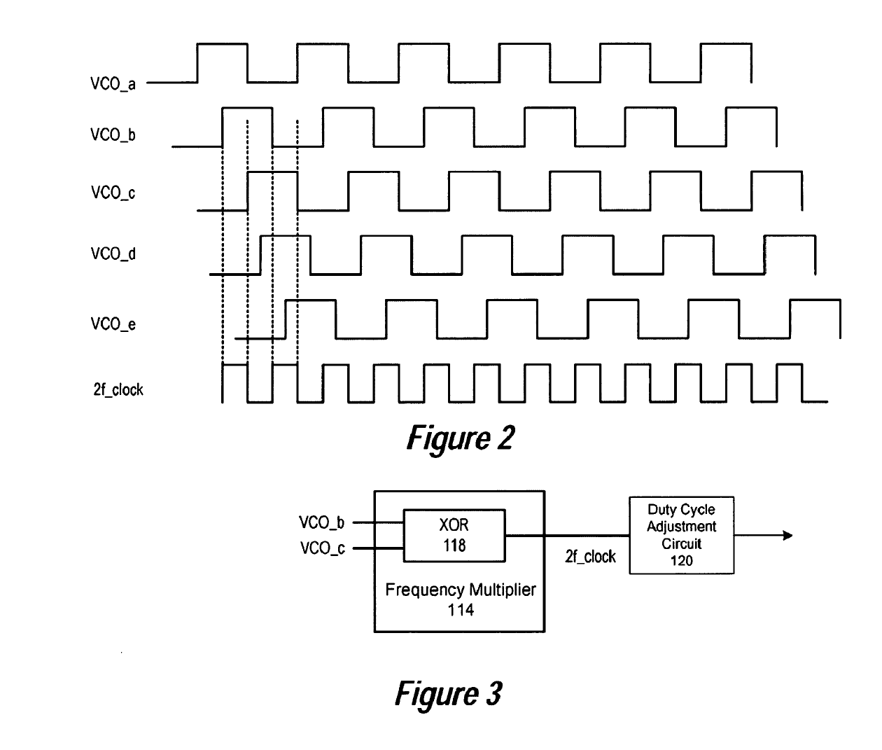

In one embodiment of the invention, the VCO 108 is a five-phase VCO with the five available phases shown in FIG. 2 as VCO_a, VCO_b, VCO_c, VCO_d, and VCO_e with a phase separation of 72 degrees. If the signal has rail-to-rail swing, then a simple “exclusive OR” (XOR) circuit 118, shown in FIG. 3, can be used by the frequency multiplier 114 to generate a signal twice the frequency of the output signal of the VCO 208 by performing and XOR operation on waveforms from two adjacent phases. For example, as shown in FIG. 2, an XOR operation performed on VCO_b and VCO_c to generate a signal with doubled frequency of the VCO. In this case, the pulse width of the “2f_clock” is “72 degrees” and the period is “180 degrees”. The duty cycle of the clock is 40%. If the divider is sensitive to duty cycle of the clock, then a duty cycle adjustment circuit 120 can be used to adjust the duty cycle after the XOR.

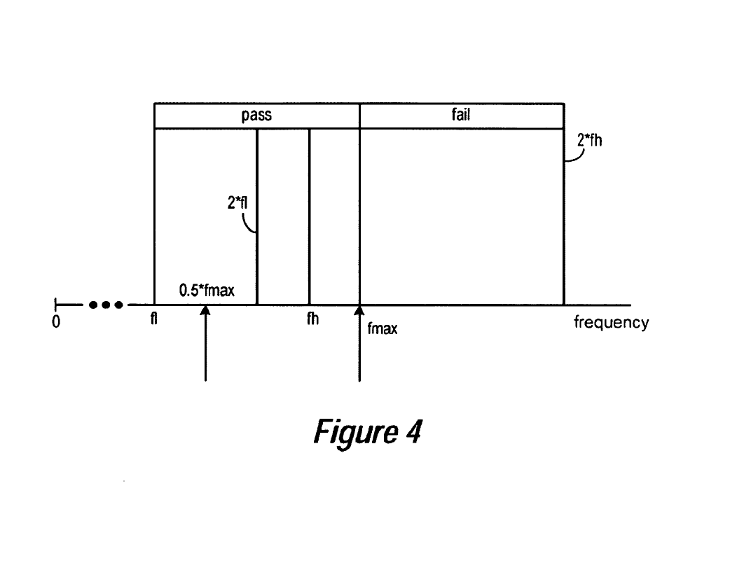

FIG. 4 is a graphical representation of the frequency ranges used for determining fmax testing of the divider 110 shown in FIG. 1. The frequencies fl and fh are the minimum and maximum frequencies of the PLL lock frequency, respectively. To determine the fmax of the divider 110, the operating parameters of the phase-locked loop are adjusted to cause the PLL lock frequency to increase from fl to fh. For the example shown, the ratio between fh and fl is larger than 2, as is the case for many applications, such as the PLLs used in microprocessor and DSPs. Since the frequency divider 116 is always subjected to a higher clock frequency than frequency divider 110, it should fail first. The frequency multiplier 114 feeds the divider 116 with frequency of 2*fl and 2*fh with 2*fl less than fh. If the outputs of the two dividers are measured, the comparator 117 will determine that the two clocks are locked in a predetermined ratio, so long as the PLL lock frequency is within the fmax of the frequency divider 110. As discussed above, the fmax of the frequency divider 110 will be the highest frequency of the output signal from the frequency multiplier 114 prior to failure of the frequency divider 116. If PLL fails lock due to VCO 108, the fmax of the frequency divider 110 will be equal to fh.

The circuitry for measuring the maximum operating frequency of a frequency divider described herein is embedded in a plurality of data processing circuits in integrated circuits that are used in information handling systems and in a wide range of other applications. Those of skill in the art will understand that the embodiments described herein will result in improved performance and an increased effective lifetime for such products. Although the present invention has been described in detail, it should be understood that various changes, substitutions and alterations can be made hereto without departing from the spirit and scope of the invention as defined by the appended claims.

What is claimed is:

1. A system for measuring the maximum operating frequency of a frequency divider, comprising:
clock generation circuitry operable to generate a first clock signal at a first frequency and a second clock signal at a second frequency, said second frequency being higher than said first frequency;
a first frequency divider operable to receive said first clock signal and to generate a first divided clock signal therefrom;
a second frequency divider operable to receive said second clock signal and to generate a second divided clock signal therefrom, said second clock signal having operating characteristics identical to said first frequency divider circuit, and wherein said first and second divided clock signals have a predetermined ratio when said second frequency divider is operating at or below its maximum operating frequency; and
detection circuitry operable to monitor the ratio of first and second divided clock signals and to generate an indication of the maximum operating frequency upon a determination that said first and second divided frequencies no longer have said predetermined ratio.

2. The system of claim 1, wherein said clock generation circuitry comprises a voltage-controlled oscillator (VCO).

3. The system of claim 2, wherein said VCO comprises a plurality of phases.

4. The system of claim 3, wherein said clock generation circuitry further comprises a frequency multiplier operable to receive said first clock signal and to generate said second clock signal therefrom.

5. The system of claim 4, wherein said second clock signal is generated using two of said phases of said VCO.

6. The system of claim 5, wherein said second clock signal is generated by performing an exclusive OR operation on said two phases of said VCO.

7. The system of claim 6, wherein said frequency of said second clock signal is twice the frequency of said first clock signal.

8. A method for generating a clock signal, comprising:
using clock generation circuitry operable to generate a first clock signal at a first frequency and a second clock signal at a second frequency;
using a first frequency divider to receive said first clock signal and to generate a first divided clock signal therefrom;
using a second frequency divider to receive said second clock signal and to generate a second divided clock signal therefrom, said second clock signal having operating characteristics identical to said first frequency divider circuit, and wherein said first and second divided clock signals have a predetermined ratio when said second frequency divider is operating at or below its maximum operating frequency; and
using detection circuitry to monitor the ratio of first and second divided clock signals and to generate an indication of the maximum operating frequency upon a determination that said first and second divided frequencies no longer have said predetermined ratio.

9. The method of claim 8, wherein said clock generation circuitry comprises a voltage-controlled oscillator (VCO).

10. The method of claim 9, wherein said VCO comprises a plurality of phases.

11. The method of claim 10, wherein said clock generation circuitry further comprises a frequency multiplier operable to receive said first clock signal and to generate said second clock signal therefrom.

12. The method of claim 12, wherein said second clock signal is generated using two of said phases of said VCO.

13. The method of claim 12, wherein said second clock signal is generated by performing an exclusive OR operation on said two phases of said VCO.

14. The method of claim 13, wherein said frequency of said second clock signal is twice the frequency of said first clock signal.

15. An information handling system, comprising:
a plurality of integrated circuits operable coupled to process data, wherein at least one integrated circuit comprises:
clock generation circuitry operable to generate a first clock signal at a first frequency and a second clock signal at a second frequency;
a first frequency divider operable to receive said first clock signal and to generate a first divided clock signal therefrom;
a second frequency divider operable to receive said second clock signal and to generate a second divided clock signal therefrom, said second clock signal having operating characteristics identical to said first frequency divider circuit, and wherein said first and second divided clock signals have a predetermined ratio when said second frequency divider is operating at or below its maximum operating frequency; and
detection circuitry operable to monitor the ratio of first and second divided clock signals and to generate an indication of the maximum operating frequency upon a determination that said first and second divided frequencies no longer have said predetermined ratio.

16. The information of claim 15, wherein said clock generation circuitry comprises a voltage-controlled oscillator (VCO).

17. The information of claim 16, wherein said VCO comprises a plurality of phases.

18. The information of claim 17, wherein said clock generation circuitry further comprises a frequency multiplier operable to receive said first clock signal and to generate said second clock signal therefrom.

19. The information of claim 18, wherein said second clock signal is generated using two of said phases of said VCO.

20. The information of claim 19, wherein said second clock signal is generated by performing an exclusive OR operation on said two phases of said VCO.
